(19) United States
(12) Patent Application Publication
(10) Pub. No.: US 2016/0276469 A1
(43) Pub. Date: Sep. 22, 2016

(54) VERTICAL-TYPE SEMICONDUCTOR DEVICE

(71) Applicant: TOYOTA JIDOSHA KABUSHIKI KAISHA, Toyota-shi, Aichi-ken (JP)

(72) Inventors: Satoru MACHIDA, Nagakute-shi (JP); Yusuke YAMASHITA, Nagakute-shi (JP); Masaru SENOO, Okazaki-shi (JP); Jun OKAWARA, Nisshin-shi (JP); Yasuhiro HIRABAYASHI, Toyota-shi (JP); Hiroshi HOSOKAWA, Toyota-shi (JP)

(73) Assignee: TOYOTA JIDOSHA KABUSHIKI KAISHA, Toyota-shi, Aichi-ken (JP)

(21) Appl. No.: 15/028,868

(22) PCT Filed: Oct. 7, 2014
(86) PCT No.: PCT/JP2014/076781

§ 371 Date: Apr. 12, 2016

(30) Foreign Application Priority Data
Dec. 5, 2013 (JP) 2013-251994

(51) Int. Cl. H01L 29/739; H01L 29/861; H01L 29/08; H01L 29/78

(52) U.S. Cl. CPC H01L 29/7397; H01L 29/7802; H01L 29/8611; H01L 29/083; H01L 29/0878

(57) ABSTRACT

A buffer layer includes an n⁺-type first buffer region and an n⁺-type second buffer region. The first buffer region is provided at a first depth from a first main surface of a semiconductor layer and has an impurity concentration higher than an impurity concentration of a drift layer. The second buffer region is provided at a second depth from the first main surface of the semiconductor layer and has an impurity concentration higher than the impurity concentration in the drift layer, the second depth being shallower than the first depth. The first buffer region delimits an opening in a plane of the semiconductor layer at the first depth. The second buffer region delimits an opening in a plane of the semiconductor layer at the second depth.

### TECHNICAL FIELD

This application claims priority to Japanese Patent Application No. 2013-251994 filed on Dec. 5, 2013, the entire contents of which are hereby incorporated by reference into the present application.

The technique disclosed in the present description relates to a vertical-type semiconductor device.

### BACKGROUND ART

As an example of the vertical-type semiconductor device, a punch through-type IGBT (Insulated Gate Bipolar Transistor) has been known. When the punch through-type IGBT is turned off, a depletion layer that extends from a junction surface between an n-type drift layer and a p-type base layer goes beyond the drift layer and reaches an n⁺-type buffer layer. Accordingly, carries in the drift layer are instantaneously depleted at turn-off, causing a rapid decrease in current. When carriers in the drift layer are depleted, the punch through-type IGBT becomes equivalent to a capacitor having a depletion layer capacitance, and this capacitor causes a resonance phenomenon between the capacitor itself and a parasitic inductance in a circuit. Consequently, due to the resonance phenomenon, a collector-emitter voltage oscillates at the turn-off of the punch through-type IGBT.

To suppress the oscillations in collector-emitter voltage, Japanese Patent Application Publication No. 2004-193212 discloses a punch through-type IGBT that includes two buffer regions provided apart in a thickness direction of a semiconductor layer. When this punch through-type IGBT is turned off, the extension of the depletion layer, which extends from the junction surface between the n-type drift layer and the p-type base layer, stops at the buffer region disposed closer to the junction surface. Accordingly, carriers remain between the two butler regions, and hence a decrease in current at turn-off becomes moderate, and the oscillations in collector-emitter voltage are suppressed.

To moderate the decrease in current at turn-off, it is important to allow the carriers that remain between the two buffer regions to appropriately flow into the drift layer. Japanese Patent Application Publication No. 2009-218543 discloses a punch through-type IGBT in which the buffer regions disposed closer to the junction surface (which are shown as an n+-type diffusion region in Japanese Patent Application Publication No. 2009-218543) are distributedly disposed in an in-plane direction of the semiconductor layer. If the buffer regions disposed closer to the junction surface are distributedly disposed, it becomes easier for the remaining carriers to flow into the drift layer through between these buffer regions. The decrease in current at turn-off thereby becomes moderate, and the oscillations in collector-emitter voltage are suppressed.

### SUMMARY OF INVENTION

### Technical Problem

It is desirable to further increase remaining carriers at turn-off, and further suppress the oscillation phenomenon. The present description has an object of providing a vertical-type semiconductor device in which the oscillation phenomenon is suppressed.

### Solution to Technical Problem

One embodiment of a vertical-type semiconductor device disclosed herein comprises a semiconductor layer, a first main electrode that coats a first main surface of the semiconductor layer, and a second main electrode that coats a second main surface of the semiconductor layer. The semiconductor layer comprises a buffer layer, a first semiconductor layer of a first conductivity-type and a second semiconductor layer of a second conductivity-type. The first semiconductor layer is in contact with the buffer layer and disposed closer to the second main surface relative to the buffer layer. The second semiconductor layer is in contact with the first semiconductor layer and disposed closer to the second main surface relative to the first semiconductor layer. The buffer layer comprises a first buffer region of the first conductivity-type and a second buffer region of the first conductivity-type. The first buffer region is formed at a first depth from the first main surface and has an impurity concentration higher than an impurity concentration of the first semiconductor layer. Further, the first buffer region delimits an opening in a plane of the semiconductor layer at the first depth. The second buffer region is formed at a second depth from the first main surface and has an impurity concentration higher than the impurity concentration of the first semiconductor layer, the second depth being shallower than the first depth. The second buffer region delimits an opening in a plane of the semiconductor layer at the second depth.

In the vertical-type semiconductor device in the above-described embodiment, remaining carriers between the first buffer region and the second buffer region can appropriately flow into the first semiconductor layer via the opening delimited by the first buffer region. Accordingly, the decrease in current at turn-off becomes moderate, and the oscillations in collector-emitter voltage are suppressed. Furthermore, in the vertical-type semiconductor device in the above-described embodiment, the second buffer region also delimits the opening. Accordingly, at turn-off, carriers can also remain in the opening delimited by the second buffer region. Accordingly, a large amount of carriers remain at the tam-off, and hence the oscillations in collector-emitter voltage are further suppressed.

### BRIEF DESCRIPTION OF DRAWINGS

FIG. 1 schematically shows a cross-sectional view of a main part of a semiconductor device in a first embodiment;

FIG. 2 shows an impurity concentration profile of the semiconductor device in a thickness direction in the first embodiment;

FIG. 3A schematically shows a cross-sectional view of a main part of a proximity of a buffer region in a first comparative example;

FIG. 38 shows a progression of a collector-emitter voltage at turn-off of a structure in FIG. 3A;

FIG. 4A schematically shows a cross-sectional view of a main part of a proximity of a buffer region in a second comparative example;

FIG. 4B shows a progression of a collector-emitter voltage at turn-off of a structure in FIG. 4A;

FIG. 5A schematically shows a cross-sectional view of a main part of a proximity of a buffer region in a third comparative example;

FIG. 5B shows a progression of a collector-emitter voltage at turn-off of a structure in FIG. 5A;

FIG. 6A schematically shows a cross-sectional view f a main part of a proximity of a buffer region in the first embodiment;

FIG. 6B shows a progression of a collector-emitter voltage at turn-off of a structure in FIG. 6A;

FIG. 7 shows a relation between an opening width of the buffer region and an oscillation time in the semiconductor device in the first embodiment;

FIG. 8 schematically shows a cross-sectional view of a main part of a semiconductor device in a variation of the first embodiment; and

FIG. 9 schematically shows a cross-sectional view of a main part. of a semiconductor device in a second embodiment.

### DESCRIPTION OF EMBODIMENTS

### Preferred Aspects of Invention

Some of technical features disclosed in this description are summarized below. Note that matters described below respectively independently have technical utility.

One embodiment of a vertical-type semiconductor device disclosed herein may comprise a semiconductor layer, a first main electrode that coats a first main surface of the semiconductor layer, and a second main electrode that coats a second main surface of the semiconductor layer. The semiconductor layer may comprise a buffer layer, a first semiconductor layer of a first conductivity-type, and a second semiconductor layer of a second conductivity-type. The first semiconductor layer is in contact with the buffer layer and disposed closer to the second main surface relative to the buffer layer. The second semiconductor layer is in contact with the first semiconductor layer and disposed closer to the second main surface relative to the first semiconductor layer. Here, the type of the vertical-type semiconductor device disclosed herein is not particularly limited. For example, the vertical-type semiconductor devices include an IGBT, a diode, and a MOSFET. If the vertical-type semiconductor device is an IGBT, the first main electrode may be a collector electrode, the second main electrode may be an emitter electrode, the first semiconductor layer may be a drift layer, and the second semiconductor layer may be a base layer. If the vertical-type semiconductor device is a diode, the first main electrode may be a cathode electrode, the second main electrode may be an anode electrode, the first semiconductor layer may be a drift layer, and the second semiconductor layer may be an anode layer. If the vertical-type semiconductor device is a MOSFET, the first main electrode may be a drain electrode, the second main electrode may be a source electrode, the first semiconductor layer may be a drift layer, and the second semiconductor layer may be a body layer.

The buffer layer may comprise a first buffer region of the first conductivity-type and a second buffer region of the first conductivity-type. The first buffer region is provided at a first depth from the first main surface and has an impurity concentration higher than an impurity concentration of the first semiconductor layer. The second buffer region is provided at a second depth from the first main surface and has an impurity concentration higher than the impurity concentration of the first semiconductor layer, the second depth being shallower than the first depth. The first buffer region delimits an opening in a plane of the semiconductor layer at the first depth. The first buffer region may also be configured as a layer that extends in the plane of the semiconductor layer at the first depth and has one or more openings provided therein. Alternatively, the first buffer region may also be configured as a set of a plurality of regions distributedly disposed in the plane of the semiconductor layer at the first depth (in this case, an opening is delimited between the regions). The second buffer region delimits an opening in a plane of the semiconductor layer at the second depth. The second buffer region may also be configured as a layer that extends in the plane of the semiconductor layer at the second depth and has one or more openings formed therein. Alternatively, the second buffer region may also be configured as a set of a plurality of regions distributedly disposed in the plane of the semiconductor layer at the second depth (in this case, an opening is delimited between the regions). A region between the first buffer region and the second buffer region is desirably a first conductivity-type region having an impurity concentration lower than the impurity concentration of the first buffer region and the impurity concentration of the second buffer region. In this case, the region between the first buffer region and the second buffer region can allow a large amount of carriers to remain.

The first buffer region may have a peak of the impurity concentration at the first depth from the first main surface. The opening delimited by the first buffer region is desirably a first conductivity-type region having an impurity concentration lower than the impurity concentration of the first buffer region. In this case, the opening delimited by the first buffer region can allow the remaining carriers to appropriately flow into the first semiconductor layer.

The second buffer region may have a peak of the impurity concentration at the second depth from the first main surface. The opening delimited by the second buffer region is desirably a first conductivity-type region having an impurity concentration lower than the impurity concentration of the second buffer region. In this case, the opening delimited by the second buffer region can allow a large amount of carriers to remain.

When observed from a direction orthogonal to the first main surface of the semiconductor layer, a position of the opening delimited by the first buffer region and a position of the opening delimited by the second buffer region desirably do not coincide with each other. More preferably, when observed from the direction orthogonal to the first main surface of the semiconductor layer, the position of the opening delimited by the first buffer region and the position of the opening delimited by the second buffer region desirably do not overlap. In these cases, at the turn-off of the vertical-type semiconductor devise, it is possible to suppress the depletion layer, which extends from the junction surface between the first semiconductor layer and the second semiconductor layer, from extending beyond the opening in the first buffer region and the opening in the second buffer region.

### First Embodiment

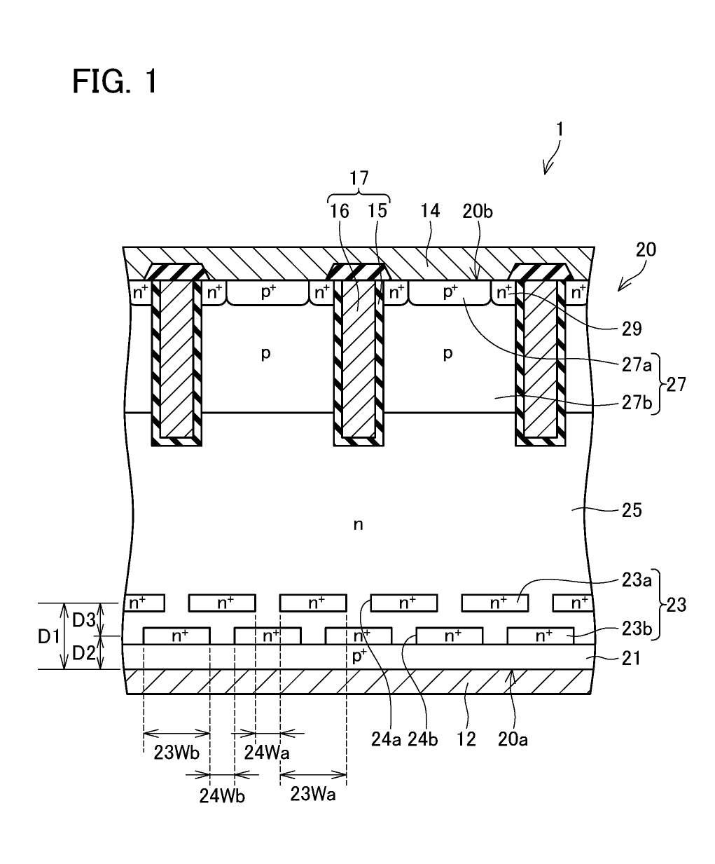

As shown in FIG. 1, a semiconductor device 1 is a vertical-type IGBT (Insulated Gate Bipolar Transistor), and includes a semiconductor layer 20, a collector electrode 12 that coats a first main surface 20a of the semiconductor layer 20, an emitter electrode 14 that coats a second main surface 20b of the semiconductor layer 20, and an insulated gate portion 17. As one example, a material of the semiconductor layer 20 is silicon.

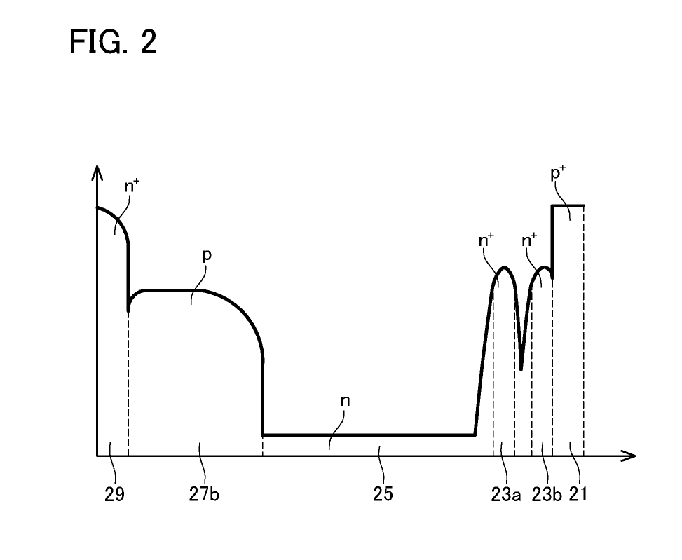

As shown in FIGS. 1 and 2, the semiconductor layer 20 comprises a p⁺-type collector layer 21, a buffer layer 23, an n-type drift layer 25, a p-type base layer 27, and an n⁺-type emitter region 29.

The collector layer 21 is located in a back layer portion of the semiconductor layer 20, and in contact with the collector electrode 12. The collector layer 21 can be formed by utilizing an ion implantation technology, and introducing impurities from the first main surface 20a of the semiconductor layer 20. As an example, the collector layer 21 has an impurity concentration of ×10¹⁷ to 5×10²⁰ cm⁻³.

The buffer layer 23 is located on the collector layer 21, and separates the collector layer 21 and the drift layer 25. The buffer layer 23 comprises a first buffer region 23a and a second buffer region 23b. The first buffer region 23a is located in the buffer layer 23 on the drift layer 25 side, and in contact with the drift layer 25. The second buffer region 23b is located in the buffer layer 23 on the collector layer 21 side, and in contact with the collector layer 21.

The first buffer region 23a has a peak of the impurity concentration at a first depth D1 from the first main surface 20a of the semiconductor layer 20. As an example, a peak value of the impurity concentration in the first buffer region 23a is 1×10¹⁶ to 1×10¹⁹ cm⁻³. Here, the first buffer region 23a is defined by a range until the peak value of the impurity concentration is reduced by an order of magnitude. As an example, the thickness of the first buffer region 23a is 0.5 to 5.0 μm. The first buffer region 23a delimits an opening 24a in a plane of the semiconductor layer 20 at the first depth D1. In other words, in the plane of the semiconductor layer 20 at the first depth D1, there exist a high-concentration part having a high impurity concentration and a low-concentration part having a low impurity concentration, and the high-concentration part corresponds to the first buffer region 23a, and the low-concentration part corresponds to the opening 24a. For example, the first buffer region 23a may also be configured as a set of a plurality of the high-concentration parts. In this case, regarding the first buffer region 23a, when observed from a direction orthogonal to the first main surface 20a of the semiconductor layer 20 cup-to-down and down-to-up directions of the paper surface of FIG. 1), the plurality of the high-concentration parts may be disposed in a stripe-like manner, or the plurality of the high-concentration parts may be disposed distributedly in a dot-like manner. Alternatively, the first buffer region 23a may also be configured as a layer that extends in the plane of the semiconductor layer 20 at the first depth D1 and has a plurality of the openings 24a distributedly formed therein. The first buffer region 23a in the present embodiment is an example in which a plurality of the high-concentration parts is disposed in a stripe-like manner. As an example, a width 23Wa of each of the high-concentration parts in the first buffer region 23a in a plane direction is 0.5 to 50 μm. As an example, a width 24Wa of each of the openings 24a delimited by the first buffer region 23a (a distance between the adjacent high-concentration parts in the first buffer region 23a) is 0.5 to 5 μm.

The second buffer region 23b has a peak of the impurity concentration at a second depth D2 from the first main surface 20a of the semiconductor layer 20. When measured from the first main surface 20a, the second depth D2 is shallower than the first depth D1. As an example, a peak value of the impurity concentration in the second buffer region 23b is 1×10¹⁶ to 1×10¹⁹ cm⁻³. Here, the second buffer region 23b is defined by a range until the peak value of the impurity concentration is reduced by an order of magnitude. As an example, the thickness of the second buffer region 23b is 0.5 to 5.0 μm. The second buffer region 23b delimits an opening 24b in a plane of the semiconductor layer 20 at the second depth D2. In other words, in the plane of the semiconductor layer 20 at the second depth D2, there exist a high-concentration part having a high impurity concentration and a low-concentration part having a low impurity concentration, and the high-concentration part corresponds to the second buffer region 23b, and the low-concentration part corresponds to the opening 24b. For example, the second buffer region 23b may also be configured as a set of a plurality of the high-concentration parts. In this case, regarding the second buffer region 23b, when observed from the direction orthogonal to the first main surface 20a of the semiconductor layer 20, the plurality of the high-concentration parts may be disposed in a stripe-like manner, or the plurality of the high-concentration, parts may be disposed distributedly in a dot-like manner. Alternatively, when observed from the direction orthogonal to the first main surface 20a of the semiconductor layer 20, the second buffer region 23b may also be configured as a layer that extends in the plane of the semiconductor layer 20 at the second depth D2 and has a plurality of the openings 24b distributedly formed therein. The second buffer region 23b in the present embodiment is an example in which a plurality of the high-concentration parts is disposed in a stripe-like manner. As an example, a width 23Wb of each of the high-concentration parts in the second buffer region 23b in the plane direction is 0.5 to 50 μm. As an example, a width 24Wb of each of the openings 24b delimited by the second buffer region 23b (a distance between the adjacent high-concentration parts in the second buffer region 23b) is 0.5 to 5 μm.

The first buffer region 23a and the second buffer region 23b can be formed by utilizing an ion implantation technology, and introducing impurities from the first main surface 20a of the semiconductor layer 20 at different range distances, respectively. Accordingly, a part of the buffer layer 23 into which no impurities are introduced has the impurity concentration which the semiconductor layer 20 originally has, and which is 1×10¹² to 1×10¹⁵ cm⁻³. As an example, a distance D3 between the depth D1 of the peak of the impurity concentration in the first buffer region 23a and the depth D2 of the peak of the impurity concentration in the second buffer region 23b is 0.5 to 5.0 μm. Moreover, when observed from the direction orthogonal to the first main surface 20a of the semiconductor layer 20, a pattern of a mask for forming the first buffer region 23a (which corresponds to a pattern of the opening 24a) and a pattern of a mask for forming the second buffer region 23b (which corresponds to a pattern of the opening 24b) do not coincide with each other. Accordingly, when observed from the direction orthogonal to the first main surface 20a of the semiconductor layer 20, a region of the opening 24a delimited by the first buffer region 23a and a region of the opening 24b delimited by the second buffer region 23b do not overlap.

The drift layer 25 is located on the buffer layer 23, and separates the buffer layer 23 and the base layer 27. The drift layer 25 is a part remaining after the formation of each diffusion region in the semiconductor layer 20. As an example, the drift layer 25 has the impurity concentration which the semiconductor layer 20 originally has, and which is 1×10¹² to 1×10¹⁵ cm⁻³. Notably, the drift layer 25 is an example of the claimed first semiconductor layer.

The base layer 27 is located on the drift layer 25, and comprises a contact base region 27a and a main base region 2711 The contact base region 27a is located in the base layer 27 on the emitter electrode 14 side, and in contact with the emitter electrode 14. The main base region 27b is located in the base layer 27 on the drift layer 25 side, and in contact with the drift layer 25. The contact base region 27a and the main base region 27b can be formed by utilizing an ion implantation technology, and introducing impurities from the second main surface 20b of the semiconductor layer 20 at different range distances, respectively. As an example, the contact base region 27a has an impurity concentration of 1×10¹⁷ to 5×10²⁰ cm⁻³. As an example, the main base region 27b has an impurity concentration of 1×10¹⁶ to 1×10¹⁹ cm⁻³. Notably, the base layer 27 is an example of the claimed second semiconductor layer.

The emitter region 29 is located in a front layer portion of the semiconductor layer 20, and in contact with the emitter electrode 14. The emitter region 29 can be formed by introducing impurities from the second main surface 20b of the semiconductor layer 20. As an example, the emitter region 29 has an impurity concentration of 1×10¹⁷ to 5×10²⁰ cm⁻³.

The collector electrode 12 coats the first main surface 20a of the semiconductor layer 20. As an example, a material of the collector electrode 12 is aluminum. The collector electrode 12 is in ohmic contact with the collector layer 21.

The emitter electrode 14 coats the second main surface 20b of the semiconductor layer 20. As an example, a material of the emitter electrode 14 is aluminum. The emitter electrode 14 is in ohmic contact with the contact base region 27a and the emitter region 29.

The insulated gate portion 17 is provided in a trench that penetrates the emitter region 29 and the main base region 27b from the second main surface 20b of the semiconductor layer 20 and reaches the drift layer 25. The insulated gate portion 17 faces the main base region 27b that separates the drift layer 25 and the emitter region 29. The insulated gate portion 17 comprises a gate insulating film 15 and a trench gate electrode 16 covered with the gate insulating film 15. As an example, a material of the gate insulating film 15 is a silicon oxide film. As an example, a material of the trench gate electrode 16 is polysilicon.

When a voltage higher than the voltage of the emitter electrode 14 is applied to the collector electrode 12, and a voltage higher than a threshold voltage is applied to the trench gate electrode 16, the semiconductor device 1 is brought into an on state. In the on state, an inversion layer is formed in the main base region 27b which the insulated gate portion 17 faces, and conduction is established between the collector electrode 12 and the emitter electrode 14. On the other hand, when a voltage higher than the voltage of the emitter electrode 14 is applied to the collector electrode 12, and a voltage equal to or lower than the threshold voltage is applied to the trench gate electrode 16, the inversion layer disappears and the semiconductor device 1 is brought into an off state. As such, the semiconductor device 1 functions as a switching element switched between ON and OFF based on the voltage applied to the trench gate electrode 16.

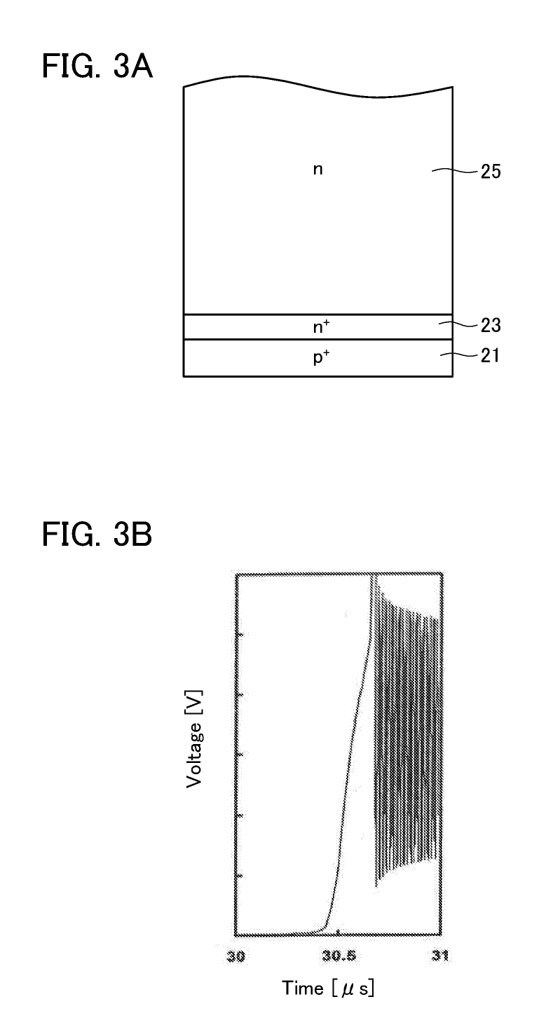

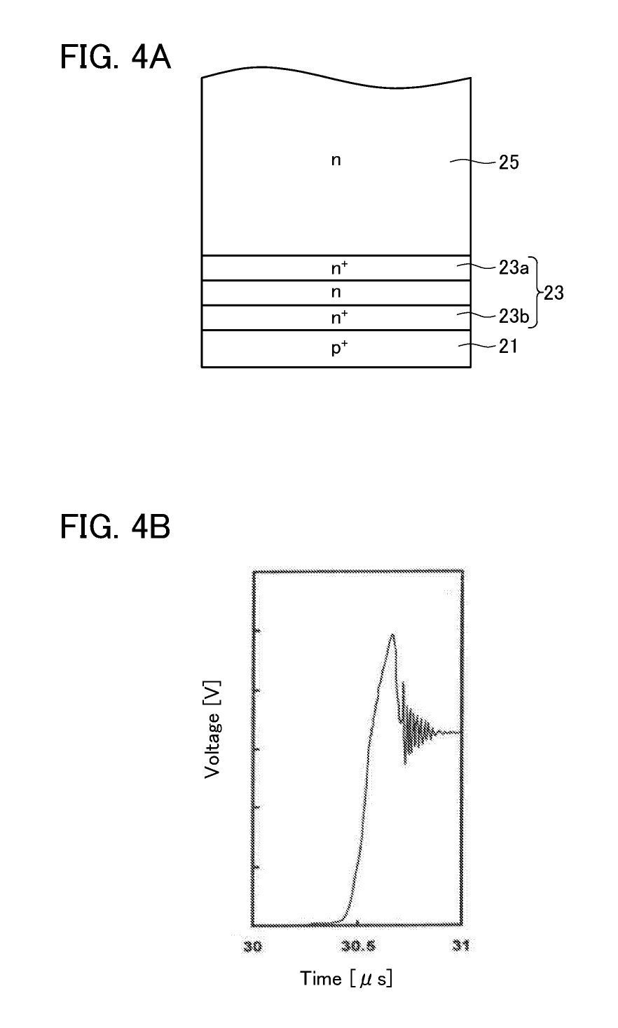

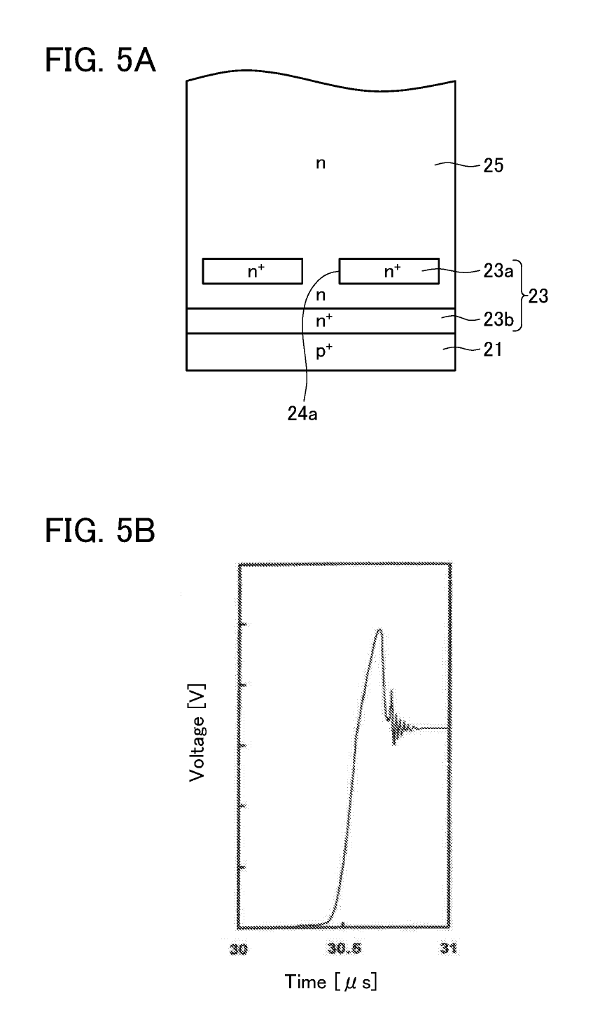

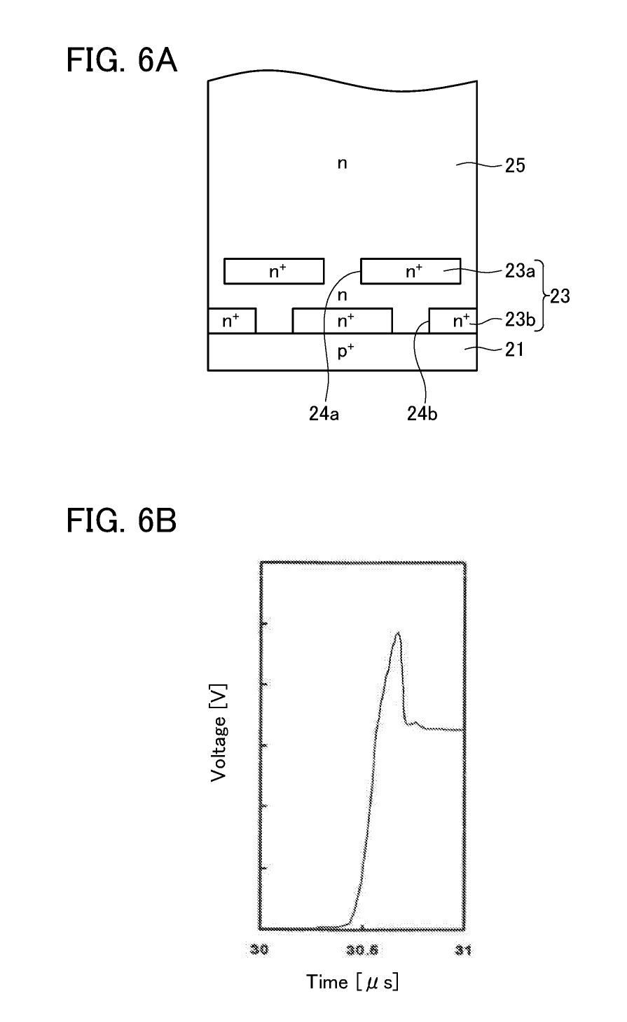

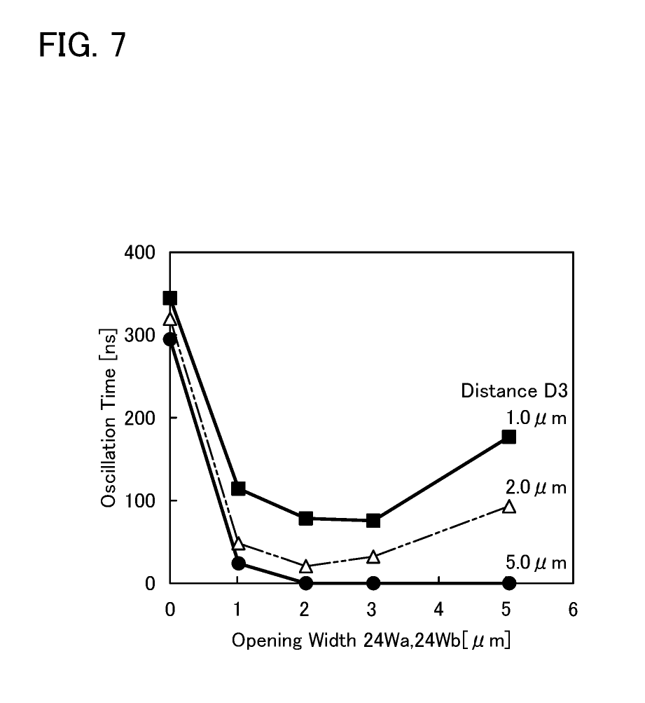

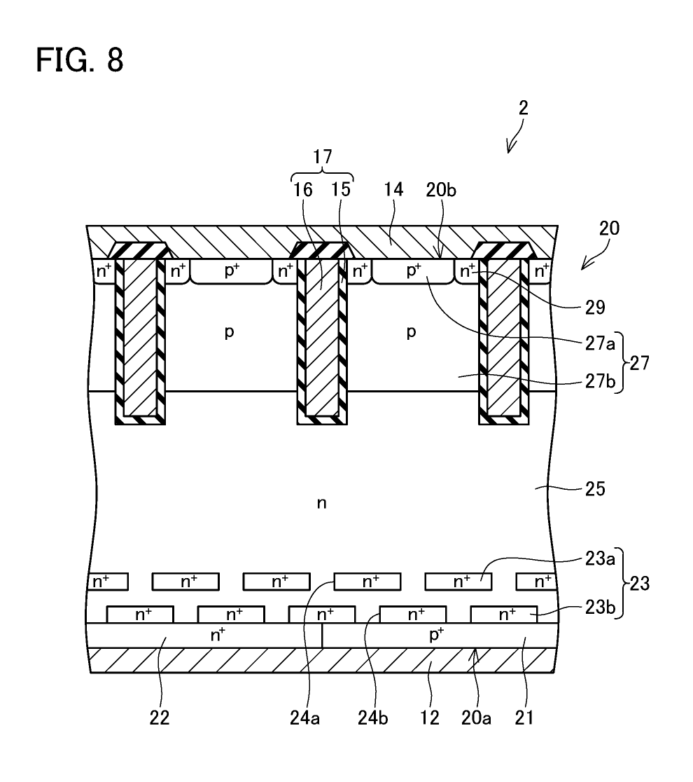

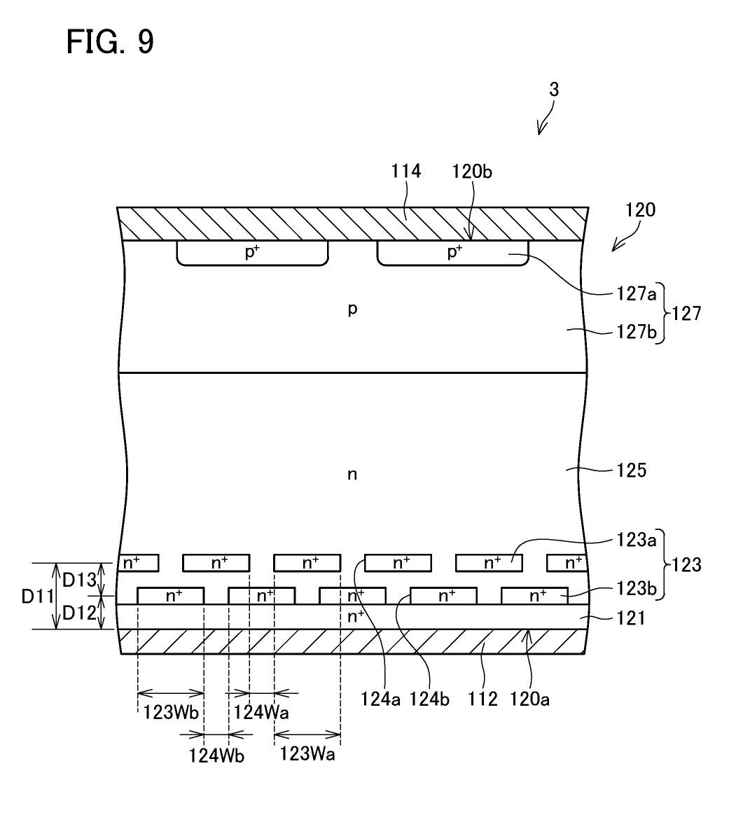

Next, with reference to FIGS. 3 to 6, characteristics of the semiconductor device 1 in the present embodiment will be described. Notably, in comparative examples described below, a component that corresponds to that in the semiconductor device 1 in the present embodiment has the same sign attached thereto, and the description thereof will be omitted.

FIG. 3A shows a first comparative example, and shows an example in which there is one peak concentration in the buffer layer 23 in the thickness direction. FIG. 4A shows a second comparative example, and shows an example in which there are two peak concentrations in the buffer layer 23 in the thickness direction. The buffer layer 23 in the second comparative example comprises the first buffer region 23a and the second buffer region 23b disposed apart the thickness direction. FIG. 5A shows a third comparative example, and shows an example in which there are two peak concentrations in the buffer layer 23 in the thickness direction. The buffer layer 23 in the third comparative example comprises the first buffer region 23a and the second buffer region 23b disposed apart in the thickness direction. Furthermore, the first buffer region 23a delimits the opening 24a. FIG. 6A shows the present embodiment, and shows an example in which there are two peak concentrations in the buffer layer 23 in the thickness direction. The buffer layer 23 in the present embodiment comprises the first buffer region 23a and the second buffer region 23b disposed apart in the thickness direction. Furthermore, the first buffer region 23a delimits the opening 24a, and the second buffer region 23b delimits the opening 24b.

As shown in FIG. 3B, in the first comparative example, the depletion layer that extends at turn-off reaches the buffer layer 23, and carriers in the drift layer 25 are instantaneously depleted, causing a rapid decrease in current. Accordingly, at the turn-off of the first comparative example, the collector-emitter voltage significantly oscillates.

As shown in FIG. 4B, in the second comparative example, the depletion layer that extends at turn-off stops at the first buffer region 23a, and hence carriers remain between the first buffer region 23a and the second buffer region 23b. Accordingly, at the turn-off of the second comparative example, the decrease in current becomes moderate, and oscillations in collector-emitter voltage are suppressed. However, at the turn-off of the second comparative example, the oscillations in collector-emitter voltage are observed.

As shown in FIG. 5B, in the third comparative example, the depletion layer that extends at turn-off stops at the first buffer region 23a, and hence carriers remain between the first buffer region 23a and the second buffer region 23b. Furthermore, at the turn-off of the third comparative example, the remaining carriers appropriately flow into the drift layer 25 via the opening 24a delimited by the first buffer region 23a, and hence the decrease in current becomes moderate, and the oscillations between the collector and the emitter are suppressed. However, at the turn-off of the third comparative example, the oscillations in collector-emitter voltage are observed.

As shown in FIG. 6B, in the present embodiment, the depletion layer that extends at turn-off stops at the first buffer region 23a, and hence carriers remain between the first buffer region 23a and the second buffer region 23b. Furthermore, at the turn-off of the present embodiment, the remaining carriers appropriately flow into the drift layer 25 via the opening 24a delimited by the first buffer region 23a, and hence the decrease in current becomes moderate, and the oscillations between the collector and the emitter are suppressed. Furthermore, in the present embodiment, the second buffer region 23b delimits the opening 24b, and hence carriers can also remain in the opening 2413 in the second buffer region 23b at turn-off. Accordingly, in the present embodiment, a large amount of carriers remain at turn-off, and hence the oscillations in collector-emitter voltage are further suppressed. At the turn-off of the present embodiment, almost no oscillations in collector-emitter voltage are observed.

FIG. 7 shows the results of an oscillation time when the opening width 24Wa delimited by the first buffer region 23a (see FIG. 1) and the opening width 24Wb delimited by the second buffer region 23b (see FIG. 1) are used as parameters. Notably, in the results shown in FIG. 7, the sum of the width 23Wa and the opening width 24Wa in the first butler region 23a is set to 8 μm, and the sum of the width 23Wb and the opening width 24Wb in the second buffer region 23b is set to 8 μm. Therefore, each of the opening widths 24Wa and 24Wb being “0” indicates an example in which an opening is not formed both in the first buffer region 23a and the second buffer region 23b (which corresponds to the above-described second comparative example). Each of the opening widths 24Wa and 24Wb being “1” indicates an example in which each of the opening width 24Wa in the first buffer region 23a and the opening width 24Wb in the second buffer region 23b is 1 μm, and each of the width 23Wa of the high-concentration part in the first buffer region 23a and the width 23Wb of the high-concentration part in the second buffer region 23b is 7 gm. Furthermore, FIG. 7 also uses, as a parameter, the distance D3 between the depth D1 of the peak of the impurity concentration in the first buffer region 23a and the depth D2 of the peak of the impurity concentration in the second buffer region 23b (see FIG. 1).

As shown in FIG. 7, if each of the opening widths 24Wa and 24Wb is increased, the oscillation time is decreased. However, it is noted that the excessively large opening widths 24Wa and 24Wb lessen the effect of decreasing the oscillation time. This is assumed to be because each of the excessively large opening widths 24Wa and 24Wb allows the depletion layer that extends at turn-off to extend beyond the first buffer region 23a, to thereby cause a decrease in amount of remaining carriers. Accordingly, each of the opening widths 24Wa and 24Wb is desirably 1 to 3 μm. In other words, when observed from the direction orthogonal to the first main surface 20a of the semiconductor layer 20, the ratio of the opening 24a to the first buffer region 23a is desirably 15 to 60%, and similarly, the ratio of the opening 24b to the second buffer region 23b is desirably 15 to 60%.

Regarding the distance D3 between the depth D1 of the peak of the impurity concentration in the first buffer region 23a and the depth D2 of the peak of the impurity concentration in the second buffer region 23b, the larger distance D3 causes the shorter oscillation time. However, in consideration of the case where the first buffer region 23a and the second buffer region 23b are activated by laser annealing from the first main surface 20a of the semiconductor layer 20, the depth DI of the first buffer region 23a is desirably 3 μm or less. Moreover, if the collector layer 21 requires a thickness of at least approximately 0.5 μm, the depth. D2 of the second buffer region 23b is 0.5 μm or more. Even in this case, the distance D3 can sufficiently be ensured, and hence the decrease in oscillation time can be observed.

The semiconductor device 1 in the present embodiment further has characteristics below.

(1) As shown in FIG. 1, in the semiconductor device 1, when observed from the direction orthogonal to the first main surface 20a of the semiconductor layer 20, a region of the opening 24a delimited by the first buffer region 23a and a region of the opening 24b delimited by the second buffer region 23b do not overlap. Accordingly, when the semiconductor device 1 is turned off, the depletion layer that extends from the junction surface between the drift layer 25 and the base layer 27 is reliably prevented from reaching the collector layer 21. Generation of punch-through between the base layer 27 and the collector layer 21 is thereby prevented, and an increase in leakage current is suppressed.

(2) The opening width 24Wa of the opening 24a delimited by the first buffer region 23a is desirably smaller than the opening width 24Wb of the opening 24b delimited by the second buffer region 23b. According to this aspect, it is possible to suppress the depletion layer, which extends at turn-off, from extending beyond the first buffer region 23a, and additionally, allow a large amount of carriers to remain in the opening 24b in the second buffer region 23b, and hence the oscillations in collector-emitter voltage are effectively suppressed.

(3) As shown in FIG. 8, the technique in the present embodiment can be applied to a semiconductor device 2, which is a reverse conducting IGBT. In the semiconductor device 2, a part of the collector layer 21 is replaced by an n⁺-type cathode layer 22. In the semiconductor device 2, both of when the IGBT structure is turned off, and when the diode structure is reverse- biased, the oscillation phenomenon is suppressed.

### Second Embodiment

As shown in FIG. 9, a semiconductor device 3 is a vertical-type Diode, and includes a semiconductor layer 120, a cathode electrode 112 that coats a first main surface 120a of the semiconductor layer 120, and an anode electrode 114 that coats a second main surface 120b of the semiconductor layer 120. As one example, a material of the semiconductor layer 120 is silicon. icon.

The semiconductor layer 120 has an n⁺-type cathode layer 121, a buffer layer 123, an n-type drift layer 125, and a p-type anode layer 27.

The cathode layer 121 is located in a back layer portion of the semiconductor layer 120, and in contact with the cathode electrode 112. The cathode layer 121 can be formed by utilizing an ion implantation technology, and introducing impurities from the first main surface 120a of the semiconductor layer 120. As an example, the cathode layer 121 has an impurity concentration of 1×10¹⁷ to 5×10²⁰ cm⁻³.

The buffer layer 123 is located on the cathode layer 121, and separates the cathode layer 121 and the drift layer 125. The buffer layer 123 includes a first buffer region 123a and a second buffer region 123b. The first buffer region 123a is located in the buffer layer 123 on the drift layer 125 side, and in contact with the drift layer 125. The second buffer region 123b is located in the buffer layer 123 on the cathode layer 121 side, and in contact with the cathode layer 121.

The first buffer region 123a has a peak of the impurity concentration at a first depth D1 1 from the first main surface 120a of the semiconductor layer 120. As an example, a peak value of the impurity concentration in the first buffer region 123a is 1×10¹⁶ to 1×10¹⁹ cm⁻³. Here, the first buffer region 123a is defined by a range until the peak value of the impurity concentration is reduced by an order of magnitude. As an example, the thickness of the first buffer region 123a is 0.5 to 5.0 μm. The first buffer region 123a delimits an opening 124a in a plane of the semiconductor layer 120 at the first depth D11. In other words, in the plane of the semiconductor layer 120 at the first depth D11, there exist a high-concentration part having a high impurity concentration and a low-concentration part having a low impurity concentration, and the high-concentration part corresponds to the first buffer region 123a, and the low-concentration part corresponds to the opening 124a. For example, the first buffer region 123a may also be configured as a set of a plurality of the high-concentration parts. In this case, regarding the first buffer region 123a, when observed from a direction orthogonal to the first main surface 120a of the semiconductor layer 120, the plurality of the high-concentration parts may be disposed in a stripe-like manner, or the plurality of the high-concentration parts may be disposed distributedly in a dot-like manner. Alternatively, the first buffer region 123a may also be configured as a layer that extends in the plane of the semiconductor layer 120 at the first depth D11 and has a plurality of the openings 124a distributedly formed therein. The first buffer region 123a in the present embodiment is an example in which a plurality of the high-concentration parts is disposed in a stripe-like manner. As an example, a width 123Wa of each of the high-concentration parts in the first buffer region 123a in a plane direction is 0.5 to 50 μm. As an example, a width 124Wa of each of the openings 124a delimited by the first buffer region 123a (a distance between the adjacent high-concentration parts in the first buffer region 123a) is 0.5 to 5 μm.

The second buffer region 123h has a peak of the impurity concentration at a second depth D12 from the first main surface 120a of the semiconductor layer 120. When measured from the first main surface 120a, the second depth D12 is shallower than the first depth D11. As an example, a peak value of the impurity concentration in the second buffer region 123b is 1×10¹⁶ to 1×10¹⁹ cm⁻³. Here, the second buffer region 123b is defined by a range until the peak value of the impurity concentration is reduced by an order of magnitude. As an example, the thickness of the second buffer region 123b is 0.5 to 5.0 μm. The second buffer region 123b delimits an opening 124b in a plane of the semiconductor layer 120 at the second depth D12. In other words, in the plane of the semiconductor layer 120 at the second depth D12, there exist a high-concentration part having a high impurity concentration and a low-concentration part having a low impurity concentration, and the high-concentration part corresponds to the second buffer region 123b, and the low-concentration part corresponds to the opening 124b. For example, the second buffer region 123b may also be configured as a set of a plurality of the high-concentration parts. In this case, regarding the second buffer region 123b, when observed from the direction orthogonal to the first main surface 120a of the semiconductor layer 120, the plurality of the high-concentration parts may be disposed in a stripe-like manner, or the plurality of the high-concentration parts may be disposed distributedly in a dot-like manner. Alternatively, when observed from the direction orthogonal to the first main surface 120a of the semiconductor layer 120, the second buffer region 123b may also be configured as a layer that extends in the plane of the semiconductor layer 120 at the second depth D12 and has a plurality of the openings 124b distributedly formed therein. The second buffer region 123b in the present embodiment is an example in which a plurality of the high-concentration parts is disposed in a stripe-like manner. As an example, a width 123Wb of each of the high-concentration parts in the second buffer region 123b in the plane direction is 0.5 to 50 μm. As an example, a width 124Wb of each of the openings 124b delimited by the second buffer region 123b (a distance between the adjacent high-concentration parts in the second buffer region 123b) is 0.5 to 5 μm.

The first buffer region 123a and the second buffer region 123b can be formed by utilizing an ion implantation technology, and introducing impurities from the first main surface 120a of the semiconductor layer 120 at different range distances, respectively. Accordingly, a part of the buffer layer 123 into which no impurities are introduced has the impurity concentration which the semiconductor layer 120 originally has, and which is 1×10¹² to 1×10¹⁵ cm⁻³. As an example, a distance D13 between the depth D11 of the peak of the impurity concentration in the first buffer region 123a and the depth D12 of the peak of the impurity concentration in the second buffer region 123b is 0.5 to 5.0 μm. Moreover, when observed from the direction orthogonal to the first main surface 120a of the semiconductor layer 120, a pattern of a mask for forming the first buffer region 123a (which corresponds to a pattern of the opening 124a) and a pattern of a mask for forming the second buffer region 123b (which corresponds to a pattern of the opening 124b) do not coincide with each other. Accordingly, when observed from the direction orthogonal to the first main surface 120a of the semiconductor layer 120, a region of the opening 124a delimited by the first buffer region 123a and a region of the opening 124b delimited by the second buffer region 123b do not overlap.

The drift layer 125 is located on the buffer layer 123, and separates the buffer layer 123 and the anode layer 127. The drift layer 125 is a part remaining after the formation of each diffusion region in the semiconductor layer 120. As an example, the drift layer 125 has the impurity concentration which the semiconductor layer 120 originally has, and which is 1×10¹² to 1×10¹⁵ cm⁻³.

The anode layer 127 is located on the drift layer 125, and comprises a high concentration anode region 127a and a low concentration anode region 127b. The contact high concentration anode region 127a is located in the anode layer 127 on the anode electrode 114 side, and in contact with the anode electrode 114. The low concentration anode region 127b is located in the anode layer 127 on the drift layer 125 side, and in contact with the drift layer 125. The high concentration anode region 127a and low concentration anode region 127b can be formed by utilizing an ion implantation technology, and introducing impurities from the second main surface 120b of the semiconductor layer 120 at different range distances, respectively. As an example, the high concentration anode region 127a has an impurity concentration of 1×10¹⁷ to 5×10²⁰ cm⁻³. As an example, the low concentration anode region 127b has an impurity concentration of 1×10¹⁶ to 1×10¹⁹ cm⁻³.

The cathode electrode 112 coats the first main surface 120a of the semiconductor layer 120. As an example, a material of the cathode electrode 112 is aluminum. The cathode electrode 112 is in ohmic contact with the cathode layer 121.

The anode electrode 114 coats the second main surface 120b of the semiconductor layer 120. As an example, a material of the anode electrode 114 is aluminum. The anode electrode 114 is in ohmic contact with the high concentration anode region 127a.

When a voltage higher than the voltage of the cathode electrode 112 is applied to the anode electrode 114 and the semiconductor device 3 is forward-biased, the semiconductor device 3 is brought into an on state. On the other hand, when a voltage higher than the voltage of the anode electrode 114 is applied to the cathode electrode 112 and the semiconductor device 3 is reverse-biased, the semiconductor device 3 is brought into an off state. As such, the semiconductor device 3 functions as a rectifier element.

In the semiconductor device 3, the depletion layer, which extends from the junction surface between the drift layer 125 and the anode layer 127 when the semiconductor device 3 is reverse-biased, stops at the first buffer region 123a, and hence carriers remain between the first buffer region 123a and the second buffer region 123b. Furthermore, when the semiconductor device 3 is reverse-biased, the remaining carriers appropriately flow into the drift layer 125 via the opening 124a delimited by the first buffer region 123a, and hence a decrease in current becomes moderate, and the oscillations between the anode and the cathode are suppressed. Furthermore, in the semiconductor device 3, the second buffer region 123b delimits the opening 124b, and hence carriers can also remain in the opening 124b in the second buffer region 123b when the semiconductor device 3 is reverse-biased. Accordingly, in the semiconductor device 3, a large amount of carriers remain when the semiconductor device 3 is reverse-biased, and hence the oscillations in anode-cathode voltage are further suppressed.

Specific examples of the present invention have been described in detail, however, these are mere exemplary indications and thus do not limit the scope of the claims. The art described in the claims includes modifications and variations of the specific examples presented above.

For example, the technique according to the buffer layer disclosed in the above-described embodiment can be applied to a MOSFET. The MOSFET has a parasitic diode embedded therein, the parasitic diode being configured with an n-type drift layer and a p-type body layer. If the technique according to the above-described buffer layer is applied in the case where this parasitic diode operates as a free wheeling diode, the oscillations are suppressed.

Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

1-5. (canceled)

6. A vertical-type semiconductor device, comprising:
a semiconductor layer;
a first main electrode that coats a first main surface of the semiconductor layer; and
a second main electrode that coats a second main surface of the semiconductor layer,
wherein
the semiconductor layer comprises:
a buffer layer;
a first semiconductor layer of a first conductivity-type that is in contact with the buffer layer and disposed closer to the second main surface relative to the buffer layer; and
a second semiconductor layer of a second conductivity-type that is in contact with the first semiconductor layer and disposed closer to the second main surface relative to the first semiconductor layer,
the buffer layer comprises:
a first buffer region of the first conductivity-type that is provided at a first depth from the first main surface and has an impurity concentration higher than an impurity concentration of the first semiconductor layer, and
a second buffer region of the first conductivity-type that is provided at a second depth from the first main surface and has an impurity concentration higher than the impurity concentration of the first semiconductor layer, the second depth being shallower than the first depth,
the first buffer region delimits an opening in a plane of the semiconductor layer at the first depth,
the second buffer region delimits an opening in a plane of the semiconductor layer at the second depth,
the opening delimited by the first buffer region is a first conductivity-type region having an impurity concentration lower than the impurity concentration in the first buffer region, and
the opening delimited by the second buffer region is a first conductivity-type region having an impurity concentration lower than the impurity concentration in the second buffer region.

7. The vertical-type semiconductor device according to claim 6, wherein,
when observed from a direction orthogonal to the first main surface of the semiconductor layer, a position of the opening delimited by the first buffer region and a position of the opening delimited by the second buffer region do not coincide with each other.

8. The vertical-type semiconductor device according to claim 7, wherein,
when observed from the direction orthogonal to the first main surface of the semiconductor layer, the position of the opening delimited by the first buffer region and the position of the opening delimited by the second buffer region do not overlap.

9. The vertical-type semiconductor device according to claim 6, wherein,
the buffer layer prevents a depletion layer that extends from a junction surface between the first semiconductor layer and the second semiconductor layer from extending beyond the buffer layer.

10. The vertical-type semiconductor device according to claim 6, wherein,
the vertical-type semiconductor device is an IGBT.
